(19) United States
(12) Patent Application Publication
(10) Pub. No.: US 2025/0126809 A1
(43) Pub. Date: Apr. 17, 2025

(54) SEMICONDUCTOR STRUCTURE

(71) Applicant: Powerchip Semiconductor Manufacturing Corporation, Hsinchu (TW)

(72) Inventors: Chun-Lin Lu, Hsinchu City (TW); Chun-Cheng Chen, Changhua County (TW); Ka Man So, Hsinchu (TW); Wei-Heng Chen, Hsinchu (TW); Shou-Zen Chang, Hsinchu City (TW)

(73) Assignee: Powerchip Semiconductor Manufacturing Corporation, Hsinchu (TW)

(21) Appl. No.: 18/525,626

(22) Filed: Nov. 30, 2023

(30) Foreign Application Priority Data
Oct. 11, 2023 (TW) 112138726

(51) Int. Cl. H10B 80/00; H01L 23/00; H01L 25/065; H01L 25/18

(52) U.S. Cl. CPC H10B 80/00; H01L 24/08; H01L 25/0657; H01L 25/18; H01L 2224/08146; H01L 2225/06541; H01L 2225/06589; H01L 2924/1431; H01L 2924/1436

(57) ABSTRACT

A semiconductor structure including device structures arranged in a stack is provided. The device structures include substrates and through-substrate vias (TSVs). The TSVs are located in the substrates. The TSVs includes first TSVs. Each of the device structures includes the corresponding substrate and the corresponding first TSV. Each of the first TSVs passes through the corresponding substrate. The number of the TSVs in the endmost device structure is less than the number of the TSVs in another of the device structures. The first TSV in the endmost device structure and the first TSV in another of the device structures are aligned with each other and electrically connected to each other.

### CROSS-REFERENCE TO RELATED APPLICATION

This application claims the priority benefit of Taiwan application serial no. 112138726, filed on Oct. 11, 2023. The entirety of the above-mentioned patent application is hereby incorporated by reference herein and made a part of this specification.

### BACKGROUND

### Technical Field

The invention relates to a semiconductor structure, and particularly relates to a semiconductor structure including through-substrate vias (TSVs).

### Description of Related Art

Currently, in order to shorten the signal transmission path and reduce the area of the semiconductor structure, a semiconductor structure formed by stacking device structures (e.g., wafer structure or chip structure) has been developed. However, how to improve the heat dissipation ability of the semiconductor structure and further shorten the signal transmission path is the goal of continuous efforts.

### SUMMARY

The invention provides a semiconductor structure, which can have better heat dissipation ability and a shorter signal transmission path.

The invention provides a semiconductor structure, which includes device structures arranged in a stack. The device structures include substrates and TSVs. The TSVs are located in the substrates. The TSVs includes first TSVs. Each of the device structures includes the corresponding substrate and the corresponding first TSV. Each of the first TSVs passes through the corresponding substrate. The number of the TSVs in the endmost device structure is less than the number of the TSVs in another of the device structures. The first TSV in the endmost device structure and the first TSV in another of the device structures are aligned with each other and electrically connected to each other.

According to an embodiment of the invention, in the semiconductor structure, the number of the TSVs in the endmost device structure may be less than the number of the TSVs in each of the remaining device structures. The first TSV in the endmost device structure and the first TSVs in the remaining device structures may be aligned with each other and electrically connected to each other.

According to an embodiment of the invention, in the semiconductor structure, the TSVs may further include second TSVs. The second TSVs are located in the substrates. Each of the second TSVs may pass through the corresponding substrate. The second TSVs in the device structures may be aligned with each other. The second TSVs aligned with each other may not be electrically connected to each other.

According to an embodiment of the invention, in the semiconductor structure, the first TSVs may be separated from each other. The second TSVs may be separated from each other.

According to an embodiment of the invention, in the semiconductor structure, the second TSVs and the first TSVs may be separated from each other.

According to an embodiment of the invention, in the semiconductor structure, one of two adjacent device structures may be hybrid bonded to the other of the two adjacent device structures.

According to an embodiment of the invention, in the semiconductor structure, the device structures may further include dielectric layers and bonding pads. The dielectric layers are located on the substrates. The bonding pads are located in the dielectric layers.

According to an embodiment of the invention, in the semiconductor structure, two adjacent dielectric layers in two adjacent device structures may be connected to each other.

According to an embodiment of the invention, in the semiconductor structure, two adjacent bonding pads in two adjacent device structures may be connected to each other.

According to an embodiment of the invention, in the semiconductor structure, the bonding pads and the first TSVs may be aligned with each other.

According to an embodiment of the invention, in the semiconductor structure, the bonding pads and the first TSVs aligned with each other may be electrically connected to each other.

According to an embodiment of the invention, in the semiconductor structure, the device structures may further include vias. The via are located in the dielectric layers. Each of the vias is located between the corresponding bonding pad and the corresponding first TSV.

According to an embodiment of the invention, in the semiconductor structure, the widths of the vias may be equal to the widths of the first TSVs.

According to an embodiment of the invention, in the semiconductor structure, the widths of the vias may be smaller than the widths of the first TSVs.

According to an embodiment of the invention, in the semiconductor structure, the bonding pads, the vias, and the first TSVs may be aligned with each other.

According to an embodiment of the invention, in the semiconductor structure, the bonding pads, the vias, and the first TSVs aligned with each other may be electrically connected to each other.

According to an embodiment of the invention, in the semiconductor structure, each of the device structures may be a wafer structure or a chip structure.

According to an embodiment of the invention, in the semiconductor structure, the endmost device structure may be a logic device structure, and the remaining device structures may be memory device structures.

According to an embodiment of the invention, in the semiconductor structure, the device structures may include a first device structure, a second device structure, and an interconnect structure. The second device structure is located on the first device structure. The interconnect structure includes a first portion, a second portion, and a third portion. The first portion is located in the first device structure. The second portion and the third portion are located in the second device structure and separated from each other. The second portion and the third portion may be connected to the first portion. The second portion and the third portion may be electrically connected to each other by the first portion.

According to an embodiment of the invention, in the semiconductor structure, the interconnect structure may include a redistribution layer (RDL), a second TSV, a conductive line, a via, a bonding pad, or a combination thereof.

Based on the above description, in the semiconductor structure according to the invention, each of the device structures includes the corresponding substrate and the corresponding first TSV. Each of the first TSVs passes through the corresponding substrate. The number of the TSVs in the endmost device structure is less than the number of the TSVs in another of the device structures. The first TSV in the endmost device structure and the first TSV in another of the device structures are aligned with each other and electrically connected to each other. Therefore, a good heat conduction path can be provided by the first TSVs aligned with each other and electrically connected to each other, thereby improving the heat dissipation ability of the semiconductor structure. In addition, a good signal transmission path can be provided and the signal transmission path can be shortened by the first TSVs aligned with each other and electrically connected to each other.

In order to make the aforementioned and other objects, features and advantages of the invention comprehensible, several exemplary embodiments accompanied with drawings are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a cross-sectional view of a semiconductor structure according to some embodiments of the invention.

FIG. 2 is a cross-sectional view of a semiconductor structure according to other embodiments of the invention.

FIG. 3 is a cross-sectional view of a semiconductor structure according to other embodiments of the invention.

FIG. 4 is an enlarged schematic view of the region R in FIG. 1.

FIG. 5 is an enlarged schematic view of the region R in FIG. 1 according to other embodiments of the invention.

### DESCRIPTION OF THE EMBODIMENTS

The embodiments are described in detail below with reference to the accompanying drawings, but the embodiments are not intended to limit the scope of the invention. For the sake of easy understanding, the same components in the following description will be denoted by the same reference symbols. In addition, the drawings are for illustrative purposes only and are not drawn to the original dimensions. In fact, the dimensions of the various features may be arbitrarily increased or reduced for clarity of discussion.

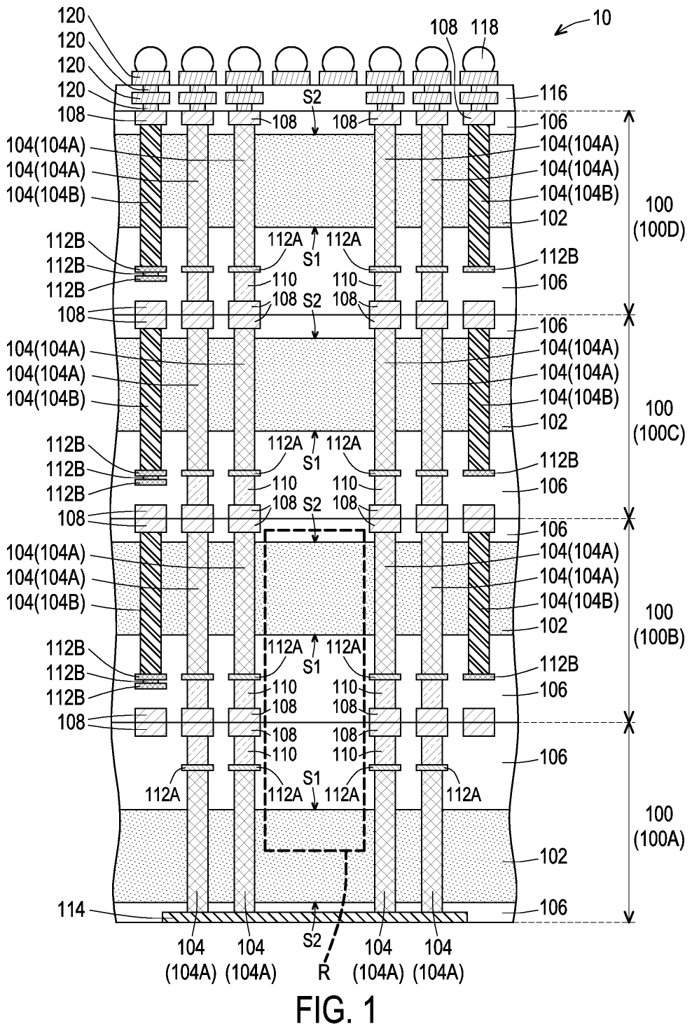

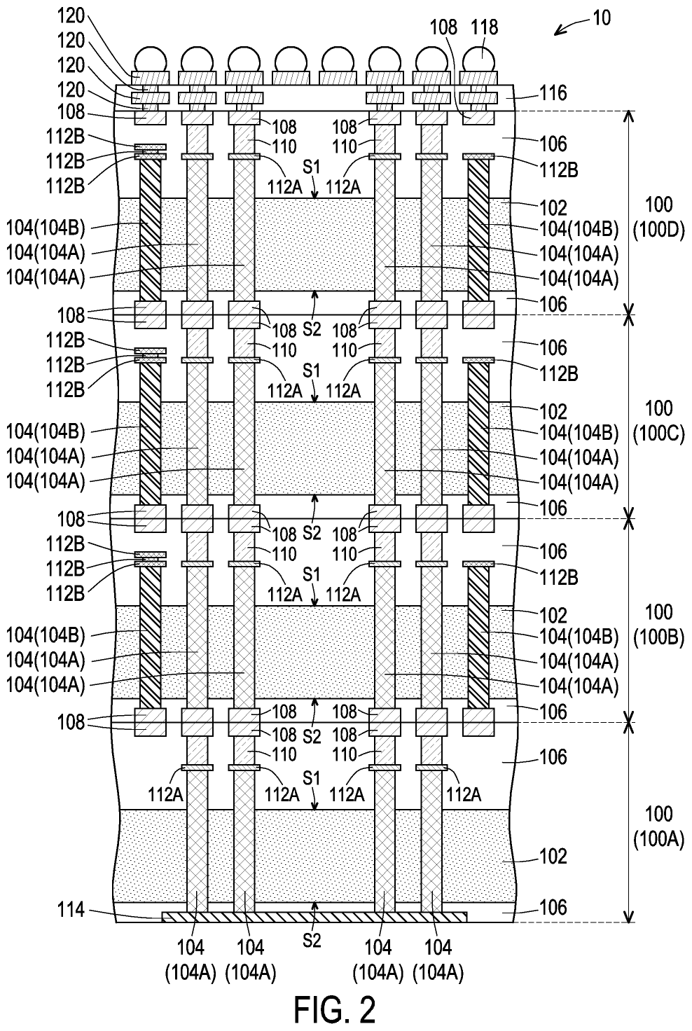

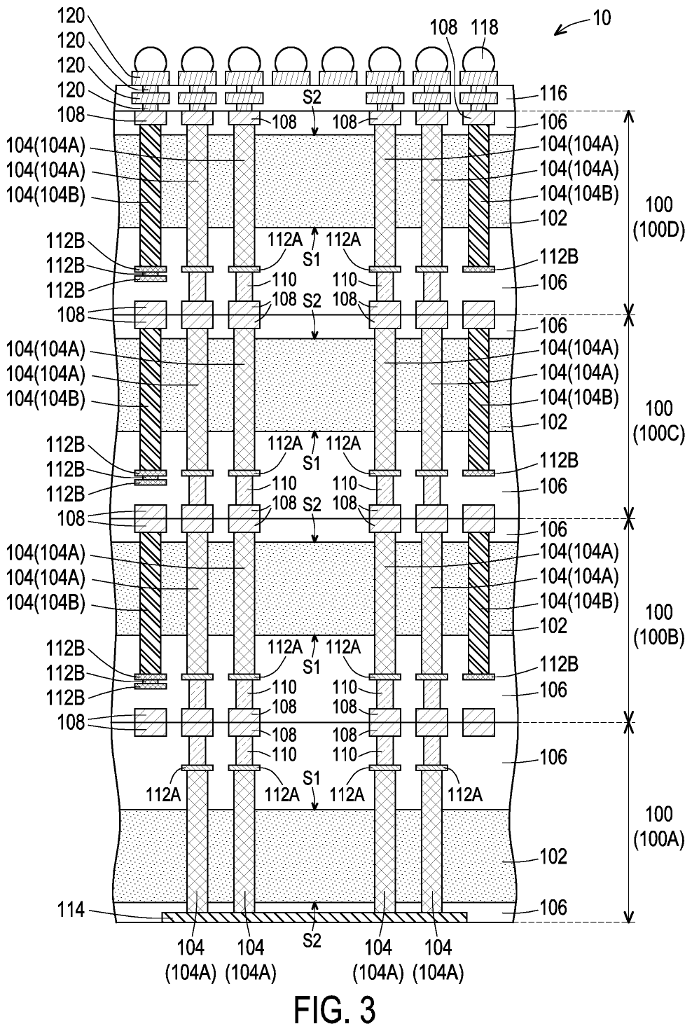

FIG. 1 is a cross-sectional view of a semiconductor structure according to some embodiments of the invention. FIG. 2 is a cross-sectional view of a semiconductor structure according to other embodiments of the invention. FIG. 3 is a cross-sectional view of a semiconductor structure according to other embodiments of the invention.

Referring to FIG. 1, a semiconductor structure 10 includes device structures 100 arranged in a stack. In addition, the number of the device structures 100 is not limited to the number shown in the figure. As long as the number of the device structures 100 is plural, it falls within the scope of the invention. For example, the device structures 100 may include a device structure 100A, a device structure 100B, a device structure 100C, and a device structure 100D. The device structure 100B is located on the device structure 100A. The device structure 100C is located on the device structure 100B. The device structure 100D is located on the device structure 100C.

In some embodiments, each of the device structures 100 may be a wafer structure or a chip structure. In some embodiments, each of the device structures 100 may be a logic device structure or a memory device structure (e.g., dynamic random access memory (DRAM) structure). That is, each of the device structures 100 may be a wafer structure including a logic device, a wafer structure including a memory device (e.g., DRAM device), a chip structure including a logic device, or a chip structure including a memory device (e.g., DRAM device). In the present embodiment, the endmost device structure 100A may be a logic device structure, and the remaining device structures 100 (e.g., device structure 100B to device structure 100D) may be memory device structures (e.g., DRAM structures).

The device structures 100 include substrates 102 and TSVs 104. In some embodiments, the substrate 102 may be a semiconductor substrate such as a silicon substrate. The TSVs 104 are located in the substrates 102. The number of the TSVs 104 in the endmost device structure 100 (e.g., device structure 100A) is less than the number of the TSVs 104 in another of the device structures 100 (e.g., device structure 100B). In some embodiments, the number of the TSVs 104 in the endmost device structure 100 (e.g., device structure 100A) may be less than the number of the TSVs 104 in each of the remaining device structures 100 (e.g., device structure 100B to device structure 100D). In some embodiments, the material of the TSV 104 is, for example, copper, tantalum, tantalum nitride, or a combination thereof. In some embodiments, there may be a dielectric layer (not shown) between the TSV 104 and the substrate 102.

The TSVs 104 include TSVs 104A. Each of the device structures 100 includes the corresponding substrate 102 and the corresponding TSV 104A. Each of the TSVs 104A passes through the corresponding substrate 102. In some embodiments, the TSV 104A may be a TSV in a device region. In some embodiments, the TSVs 104A may be separated from each other.

The TSV 104A in the endmost device structure 100 (e.g., device structure 100A) and the TSV 104A in another of the device structures 100 (e.g., device structure 100B) are aligned with each other and electrically connected to each other. Therefore, a good heat conduction path can be provided to improve the heat dissipation ability of the semiconductor structure 10, a good signal transmission path can be provided, and the signal transmission path can be shortened.

In some embodiments, the TSV 104A in the endmost device structure 100 (e.g., device structure 100A) and the TSVs 104 A in the remaining device structures 100 (e.g., device structure 100B to device structure 100D) may be aligned with each other and electrically connected to each other. Therefore, the heat dissipation ability of the semiconductor structure 10 can be further improved, a better signal transmission path can be provided, and the signal transmission path can be further shortened.

In some embodiments, the TSVs 104 may further include TSVs 104B. The TSVs 104B are located in the substrates 102. Each of the TSVs 104B may pass through the corresponding substrate 102. In some embodiments, the TSV 104B may be a TSV in an input/output (I/O) region. In some embodiments, the TSVs 104B may be separated from each other. In some embodiments, the TSVs 104B and the TSVs 104A may be separated from each other. The TSVs 104B in the device structures 100 may be aligned with each other. In some embodiments, the TSVs 104B aligned with each other may not be electrically connected to each other. In some embodiments, the TSVs 104B aligned with each other may be electrically connected to each other.

In some embodiments, one of two adjacent device structures 100 may be hybrid bonded to the other of the two adjacent device structures 100. In some embodiments, the device structures 100 may further include dielectric layers 106 and bonding pads 108. The dielectric layers 106 are located on the substrates 102. In some embodiments, two adjacent dielectric layers 106 in two adjacent device structures 100 may be bonded to each other. In some embodiments, a portion of the TSV 104 may be further located in the dielectric layer 106. In some embodiments, dielectric layer 106 may be a multilayer structure. In some embodiments, the material of the dielectric layer 106 is, for example, silicon oxide, silicon nitride, or a combination thereof.

The dielectric layers 106 may be respectively located on a front side S1 and a back side S2 of the substrate 102. The dielectric layer 106 on the front side S1 may have a front end of line (FEOL) device (e.g., logic device or memory device) (not shown), a FEOL interconnect structure (not shown), and a back end of line (BEOL) interconnect structure (not shown), and the description thereof is omitted here. In the present embodiment, as shown in FIG. 1, the front side S1 of the substrate 102 in the device structure 100B may face the front side S1 of the substrate 102 in the device structure 100A, the front side S1 of the substrate 102 in the device structure 100C may face the back side S2 of the substrate 102 in the device structure 100B, and the front side S1 of the substrate 102 in the device structure 100D may face the back side S2 of the substrate 102 in the device structure 100C, but the invention is not limited thereto. In other embodiments, as shown in FIG. 2, the back side S2 of the substrate 102 in the device structure 100B may face the front side S1 of the substrate 102 in the device structure 100A, the back side S2 of the substrate 102 in the device structure 100C may face the front side S1 of the substrate 102 in the device structure 100B, and the back side S2 of the substrate 102 in the device structure 100D may face the front side S1 of the substrate 102 in the device structure 100C.

The bonding pads 108 are located in the dielectric layers 106. In some embodiments, two adjacent bonding pads 108 in two adjacent device structures 100 may be bonded to each other. In some embodiments, the material of the bonding pad 108 is, for example, a conductive material such as copper. In some embodiments, the bonding pads 108 and the TSVs 104A may be aligned with each other. In some embodiments, the bonding pads 108 and the TSVs 104A aligned with each other may be electrically connected to each other. In some embodiments, the bonding pads 108 and the TSVs 104B may be aligned with each other. In some embodiments, the bonding pad 108 and the TSV 104B adjacent to each other may be electrically connected to each other.

In some embodiments, the device structures 100 may further include vias 110. The vias 110 are located in the dielectric layers 106. In some embodiments, the via 110 may be used as a through dielectric via (TDV). In some embodiments, the via 110 may be located in the dielectric layer 106 on the front side S1. Each of the vias 110 is located between the corresponding bonding pad 108 and the corresponding TSV 104A. In some embodiments, the bonding pads 108, the vias 110, and the TSVs 104A may be aligned with each other. In some embodiments, the bonding pads 108, the vias 110, and the TSVs 104A aligned with each other may be electrically connected to each other. In some embodiments, the material of the via 110 is, for example, copper, tantalum, tantalum nitride, or a combination thereof.

In some embodiments, the device structure 100 may further include an interconnect structure 112A and an interconnect structure 112B. In the present embodiment, as shown in FIG. 1, the via 110 may be directly connected to the bonding pad 108, and the via 110 may be electrically connected to the TSV 104A by the interconnect structure 112A, but the invention is not limited thereto. In other embodiments, the via 110 may be electrically connected to the bonding pad 108 by other interconnect structure (not shown). In the present embodiment, the interconnect structure 112A may be a single-layer structure, but the invention is not limited thereto. In other embodiments, the interconnect structure 112A may be a multilayer structure. In addition, the TSV 104B may be electrically connected to the interconnect structure 112B. In some embodiments, the material of the interconnect structure 112A and the material of the interconnect structure 112B are, for example, copper, tungsten, aluminum, tantalum, tantalum nitride, titanium, titanium nitride, or combinations thereof.

In some embodiments, as shown in FIG. 1, the widths of the vias 110 may be equal to the widths of the TSVs 104A, thereby helping to further improve the heat dissipation ability of the semiconductor structure 10. In other embodiments, as shown in FIG. 3, the widths of the vias 110 may be smaller than the widths of the TSVs 104A.

In some embodiments, the endmost device structure 100 (e.g., device structure 100A) may further include a metal layer 114. The metal layer 114 may be located in the dielectric layer 106. The metal layer 114 may be connected to the TSV 104 (e.g., TSV 104A). In some embodiments, the metal layer 114 may be used as a heat dissipation plate. In some embodiments, the metal layer 114 may be used as a redistribution layer. In some embodiments, the material of the metal layer 114 is, for example, a conductive material such as copper.

In some embodiments, the semiconductor structure 10 may further include a dielectric layer 116, connection terminals 118, and interconnect structures 120. The dielectric layer 116 is located on the dielectric layer 106 of another endmost device structure 100 (e.g., device structure 100D). In some embodiments, the dielectric layer 116 may be a multilayer structure. In some embodiments, the material of the dielectric layer 116 may be silicon oxide, silicon nitride, or a combination thereof.

Each of the connection terminals 118 may be electrically connected to the corresponding TSV 104. In some embodiments, the connection terminal 118 may be a bump (e.g., solder ball), but the invention is not limited thereto. The interconnect structure 120 are located in and on the dielectric layer 116. In some embodiments, the interconnect structure 120 may include a under-bump metallurgy (UBM), a conductive line, a via, or a combination thereof. In some embodiments, the connection terminal 118 may be electrically connected to the TSV 104 by the interconnect structure 120 and the bonding pad 108.

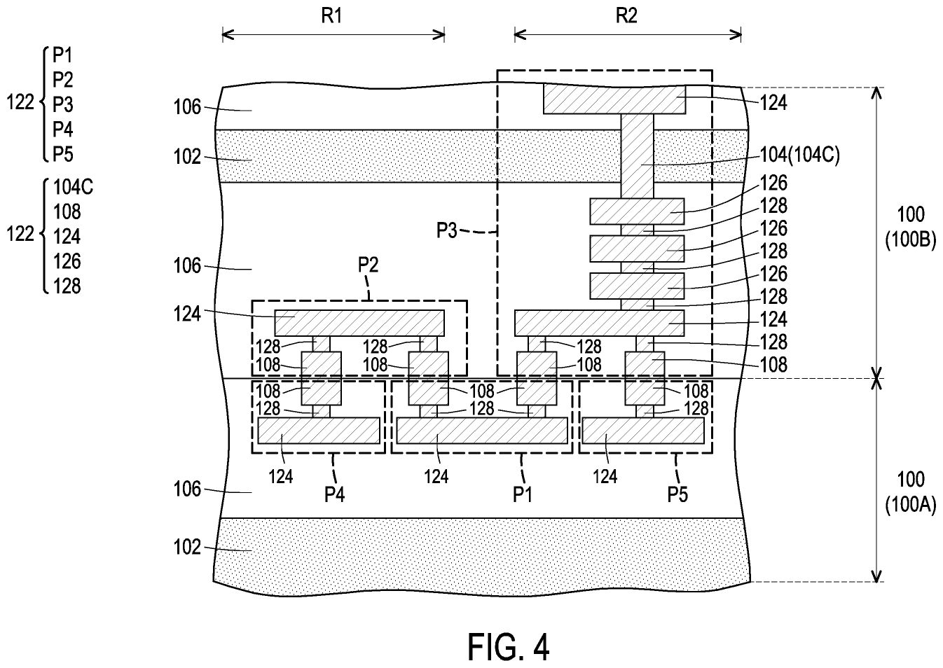

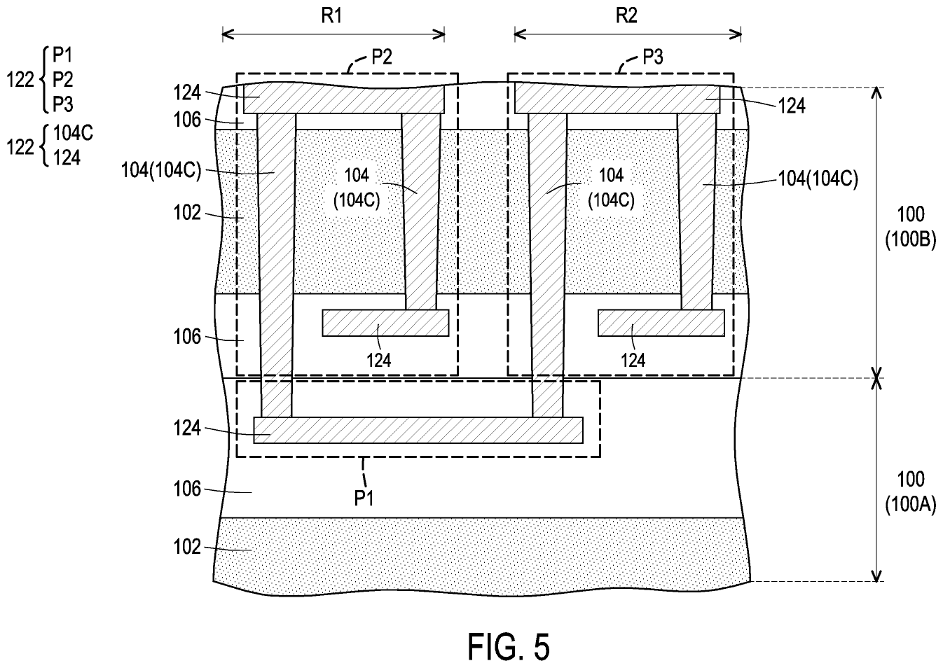

FIG. 4 is an enlarged schematic view of the region R in FIG. 1. FIG. 5 is an enlarged schematic view of the region R in FIG. 1 according to other embodiments of the invention. In addition, in FIG. 1, some components in the region R in FIG. 4 and FIG. 5 are omitted. In addition, the components in FIG. 1, FIG. 4, and FIG. 5 are not drawn to the same scale.

Referring to FIG. 4, the device structures 100 may include an interconnect structure 122. The interconnect structure 122 includes a first portion P1, a second portion P2, and a third portion P3. The first portion P1 is located in the device structure 100A. The second portion P2 and the third portion P3 are located in the device structure 100B and separated from each other. The second portion P2 and the third portion P3 may be connected to the first portion P1. The second portion P2 and the third portion P3 may be electrically connected to each other by the first portion P1. In this way, when there is a seal ring (not shown) between a first region R1 and a second region R2 of the device structure 100B, since the interconnect structure 122 may cross over the seal ring, the device (not shown) in the first region R1 and the device (not shown) in the second region R2 may be electrically connected to each other by the interconnect structure 122. In some embodiments, the interconnect structure 122 may include a fourth portion P4 and a fifth portion P5. The fourth portion P4 and the fifth portion P5 are located in the device structure 100A. The first portion P1, the fourth portion P4, and the fifth portion P5 are separated from each other. The fourth portion P4 may be connected to the second portion P2. The fifth portion P5 may be connected to the third portion P3.

In some embodiments, the interconnect structure 122 may include redistribution layers 124, a TSV 104C, conductive lines 126, vias 128, bonding pads 108, or a combination thereof. As shown in FIG. 4, the interconnect structure 122 may include the redistribution layers 124, the TSV 104C, the conductive lines 126, the vias 128, and the bonding pads 108, but the invention is not limited thereto. In other embodiments, as shown in FIG. 5, the interconnect structure 122 may not include the bonding pad 108, and the interconnect structure 122 may include the redistribution layers 124 and the TSVs 104C. In some embodiments, the material of the interconnect structure 122 may include copper, tungsten, aluminum, tantalum, tantalum nitride, titanium, titanium nitride, or a combination thereof.

In addition, in FIG. 1 to FIG. 5, the same or similar components are denoted by the same reference symbols, and the description thereof is omitted.

Based on the above embodiments, in the semiconductor structure 10, each of the device structures 100 includes the corresponding substrate 102 and the corresponding TSV 104A. Each of the TSVs 104A passes through the corresponding substrate 102. The number of the TSVs 104 in the endmost device structure 100 (e.g., device structure 100A) is less than the number of the TSVs 104 in another of the device structures 100 (e.g., device structure 100B). The TSV 104A in the endmost device structure 100 (e.g., device structure 100A) and the TSV 104A in another of the device structures 100 (e.g., device structure 100B) are aligned with each other and electrically connected to each other. Therefore, a good heat conduction path can be provided by the TSVs 104A aligned with each other and electrically connected to each other, thereby improving the heat dissipation ability of the semiconductor structure 10. In addition, a good signal transmission path can be provided and the signal transmission path can be shortened by the TSVs 104A aligned with each other and electrically connected to each other.

In summary, in the semiconductor structure of the aforementioned embodiments, the heat dissipation ability of the semiconductor structure can be improved, a good signal transmission path can be provided, and the signal transmission path can be shortened by the TSVs aligned with each other and electrically connected to each other.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A semiconductor structure, comprising device structures arranged in a stack, wherein the device structures comprise:
substrates; and
through-substrate vias (TSVs) located in the substrates and comprising first TSVs, wherein
each of the device structures comprises the corresponding substrate and the corresponding first TSV,
each of the first TSVs passes through the corresponding substrate,
the number of the TSVs in the endmost device structure is less than the number of the TSVs in another of the device structures, and
the first TSV in the endmost device structure and the first TSV in another of the device structures are aligned with each other and electrically connected to each other.

2. The semiconductor structure according to claim 1, wherein
the number of the TSVs in the endmost device structure is less than the number of the TSVs in each of the remaining device structures, and
the first TSV in the endmost device structure and the first TSVs in the remaining device structures are aligned with each other and electrically connected to each other.

3. The semiconductor structure according to claim 1, wherein the TSVs further comprise:
second TSVs located in the substrates, wherein
each of the second TSVs passes through the corresponding substrate,
the second TSVs in the device structures are aligned with each other, and
the second TSVs aligned with each other are not electrically connected to each other.

4. The semiconductor structure according to claim 3, wherein the first TSVs are separated from each other, and the second TSVs are separated from each other.

5. The semiconductor structure according to claim 3, wherein the second TSVs and the first TSVs are separated from each other.

6. The semiconductor structure according to claim 1, wherein one of two adjacent device structures is hybrid bonded to the other of the two adjacent device structures.

7. The semiconductor structure according to claim 1, wherein the device structures further comprise:
dielectric layers located on the substrates; and
bonding pads located in the dielectric layers.

8. The semiconductor structure according to claim 7, wherein two adjacent dielectric layers in two adjacent device structures are bonded to each other.

9. The semiconductor structure according to claim 7, wherein two adjacent bonding pads in two adjacent device structures are bonded to each other.

10. The semiconductor structure according to claim 7, wherein the bonding pads and the first TSVs are aligned with each other.

11. The semiconductor structure according to claim 10, wherein the bonding pads and the first TSVs aligned with each other are electrically connected to each other.

12. The semiconductor structure according to claim 7, wherein the device structures further comprise:
vias located in the dielectric layers, wherein
each of the vias located between the corresponding bonding pad and the corresponding first TSV.

13. The semiconductor structure according to claim 12, wherein widths of the vias are equal to widths of the first TSVs.

14. The semiconductor structure according to claim 12, wherein widths of the vias are smaller than widths of the first TSVs.

15. The semiconductor structure according to claim 12, wherein the bonding pads, the vias, and the first TSVs are aligned with each other.

16. The semiconductor structure according to claim 15, wherein the bonding pads, the vias, and the first TSVs aligned with each other are electrically connected to each other.

17. The semiconductor structure according to claim 1, wherein each of the device structures comprises a wafer structure or a chip structure.

18. The semiconductor structure according to claim 1, wherein the endmost device structure comprises a logic device structure, and the remaining device structures comprise memory device structures.

19. The semiconductor structure according to claim 1, wherein the device structures comprise:
a first device structure;
a second device structure located on the first device structure; and
an interconnect structure comprising:
a first portion located in the first device structure; and
a second portion and a third portion located in the second device structure and separated from each other, wherein
the second portion and the third portion are connected to the first portion, and
the second portion and the third portion are electrically connected to each other by the first portion.

20. The semiconductor structure according to claim 19, wherein the interconnect structure comprises a redistribution layer, a second TSV, a conductive line, a via, a bonding pad, or a combination thereof.
